(19) United States
(12) Patent Application Publication
(10) Pub. No.: US 2026/0020228 A1
(43) Pub. Date: Jan. 15, 2026

(54) SEMICONDUCTOR MEMORY DEVICES AND METHODS OF MANUFACTURING THE SAME

(71) Applicant: Samsung Electronics Co., Ltd., Suwon-si (KR)

(72) Inventors: SUNGHWAN JANG, Suwon-si (KR); BITNA KIM, Suwon-si (KR)

(21) Appl. No.: 19/175,471

(22) Filed: Apr. 10, 2025

(30) Foreign Application Priority Data
Jul. 9, 2024 (KR) 10-2024-0090673

(51) Int. Cl. H10B 12/00; H10B 80/00

(52) U.S. Cl. CPC H10B 12/482; H10B 12/315; H10B 12/488; H10B 12/50; H10B 80/00

(57) ABSTRACT

A semiconductor memory device includes a separation insulating layer; semiconductor patterns extending in a first direction on the separation insulating layer, wherein the semiconductor patterns are separated from each other in a second direction and a third direction, wherein each of the semiconductor patterns includes a channel region, a first impurity region, and a second impurity region; word lines that extend in the second direction respectively on the semiconductor patterns; bit lines that extend in the third direction on the separation insulating layer, wherein the bit lines are electrically connected to the first impurity regions, respectively; cell capacitors that are electrically connected to the second impurity regions, respectively; and a plate electrode that extends in the third direction on the separation insulating layer and is electrically connected to the cell capacitors.

### CROSS-REFERENCE TO RELATED APPLICATIONS

This application is based on and claims priority under 35 U.S.C. § 119 to Korean Patent Application No. 10-2024-0090673, filed on Jul. 9, 2024, in the Korean Intellectual Property Office, the disclosure of which is incorporated by reference herein in its entirety.

### BACKGROUND OF THE INVENTION

The inventive concept relates to semiconductor devices, such as semiconductor memory devices and methods of manufacturing the semiconductor (memory) devices, and more particularly, to three-dimensional semiconductor memory devices and methods of manufacturing the three-dimensional semiconductor memory devices.

As miniaturization, multi-functionality, and high performance of electronics products are needed, high-capacity semiconductor memory devices may be needed, and increased integration may be needed to provide high-capacity semiconductor memory devices. Proposed may include a three-dimensional semiconductor memory device in which memory capacity is increased by vertically stacking a plurality of memory cells on a substrate.

### SUMMARY OF THE INVENTION

The inventive concept may include a three-dimensional semiconductor memory device including a separation insulating layer that insulates a plurality of bit lines from each other, a plurality of cell capacitors from each other, and the plurality of bit lines from the plurality of cell capacitors.

The inventive concept may include a method of manufacturing a three-dimensional semiconductor memory device including a separation insulating layer that insulates a plurality of bit lines from each other, a plurality of cell capacitors from each other, and the plurality of bit lines from the plurality of cell capacitors.

Objects to be achieved by the inventive concept are not limited to the objects described above, and other objects not described above may be clearly understood by those skilled in the art from the description below.

According to an aspect of the inventive concept, a semiconductor memory device includes a separation insulating layer; a plurality of semiconductor patterns that extend in a first horizontal direction on the separation insulating layer, wherein the semiconductor patterns are separated from each other in a second horizontal direction and a vertical direction that intersect the first horizontal direction, wherein each of the semiconductor patterns includes a channel region, a first impurity region, and a second impurity region, and wherein the first impurity region and the second impurity region are arranged in the first horizontal direction with the channel region therebetween; a plurality of word lines that extend in the second horizontal direction respectively on the plurality of semiconductor patterns; a plurality of bit lines that extend in the vertical direction on the separation insulating layer, wherein the plurality of bit lines are electrically connected to the first impurity regions of the plurality of semiconductor patterns, respectively; a plurality of cell capacitors that are electrically connected to the second impurity regions of the plurality of semiconductor patterns, respectively; and a plate electrode that extends in the vertical direction on the separation insulating layer and is electrically connected to the plurality of cell capacitors, wherein the first horizontal direction and the second horizontal direction are parallel with an upper surface of the separation insulating layer, and wherein the vertical direction is perpendicular to the upper surface of the separation insulating layer.

According to an aspect of the inventive concept, a semiconductor memory device includes a first stack structure that includes a memory cell region that includes a plurality of memory cells and a plurality of cell capacitors; and a second stack structure that overlaps the plurality of memory cells in a vertical direction, wherein the second stack structure includes a peripheral circuit region that is electrically connected to the plurality of memory cells and on the first stack structure, wherein the first stack structure comprises: a separation insulating layer; a plurality of semiconductor patterns that extend in a first horizontal direction on the separation insulating layer, wherein the semiconductor patterns are separated from each other in a second horizontal direction and the vertical direction that intersect the first horizontal direction, wherein each of the semiconductor patterns includes a channel region, a first impurity region, and a second impurity region, and wherein the first impurity region and the second impurity region are arranged in the first horizontal direction with the channel region therebetween; a plurality of word lines that extend in the second horizontal direction respectively on the plurality of semiconductor patterns; a plurality of bit lines that extend in the vertical direction on the separation insulating layer and extend in a first portion of the separation insulating layer, wherein the plurality of bit lines are electrically connected to the first impurity regions of the plurality of semiconductor patterns, respectively; and a plate electrode that extends in the vertical direction on the separation insulating layer an extends in a second portion of the separation insulating layer, wherein the plate electrode is electrically connected to the plurality of cell capacitors, wherein the plurality of cell capacitors are electrically connected to the second impurity regions of the plurality of semiconductor patterns, respectively, wherein the first horizontal direction and the second horizontal direction are parallel with an upper surface of the separation insulating layer, and wherein the vertical direction is perpendicular to the upper surface of the separation insulating layer.

According to an aspect of the inventive concept, a semiconductor memory device includes a separation insulating layer; a plurality of semiconductor patterns that extend in a first horizontal direction on the separation insulating layer, wherein the semiconductor patterns are separated from each other in a second horizontal direction and a vertical direction that intersect the first horizontal direction, wherein each of the semiconductor patterns includes a channel region, a first impurity region, and a second impurity region, and wherein the first impurity region and the second impurity region are arranged in the first horizontal direction with the channel region therebetween; a plurality of word lines that extend in the second horizontal direction respectively on the plurality of semiconductor patterns; a plurality of bit lines that extend in the vertical direction on the separation insulating layer, wherein the plurality of bit lines are electrically connected to the first impurity regions of the plurality of semiconductor patterns, respectively; a plurality of cell capacitors that are electrically connected to the second impurity regions of the plurality of semiconductor patterns, respectively; and a plate electrode that extends in the vertical direction on the separation insulating layer and is electrically connected to the plurality of cell capacitors, wherein the bit lines are electrically insulated from each other by the separation insulating layer, wherein the first horizontal direction and the second horizontal direction are parallel with an upper surface of the separation insulating layer, and wherein the vertical direction is perpendicular to the upper surface of the separation insulating layer.

### BRIEF DESCRIPTION OF THE DRAWINGS

Embodiments of the inventive concept will be more clearly understood from the following detailed description taken in conjunction with the accompanying drawings in which:

FIG. 1 is a block diagram schematically illustrating a semiconductor memory device according to an embodiment;

FIG. 2 is a circuit diagram illustrating a memory cell region illustrated in FIG. 1;

FIG. 3 is a schematic perspective view illustrating a memory cell region of a semiconductor memory device according to an embodiment;

FIG. 4 is a cross-sectional view taken along line A1-A1′ of FIG. 3;

FIG. 5 to FIG. 12 are cross-sectional views illustrating a method of manufacturing a semiconductor memory device, according to an embodiment, and are cross-sectional views taken along line A1-A1′ of FIG. 3;

FIG. 13 is a cross-sectional view of a semiconductor memory device according to an embodiment, and is a cross-sectional view taken along line A1-A1′ of FIG. 3; and

FIGS. 14 to 21 are cross-sectional views illustrating a method of manufacturing a semiconductor memory device, according to an embodiment, and are cross-sectional views taken along line A1-A1′ of FIG. 3.

### DETAILED DESCRIPTION OF THE INVENTION

Hereinafter, embodiments of the inventive concept are described in detail with reference to the attached drawings. The same reference numerals are used for the same components in the drawings unless clearly described otherwise, and redundant descriptions thereof may be omitted.

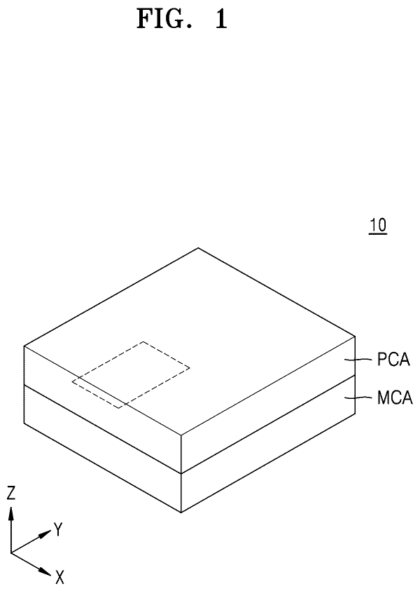

FIG. 1 is a block diagram schematically illustrating a semiconductor memory device according to an embodiment.

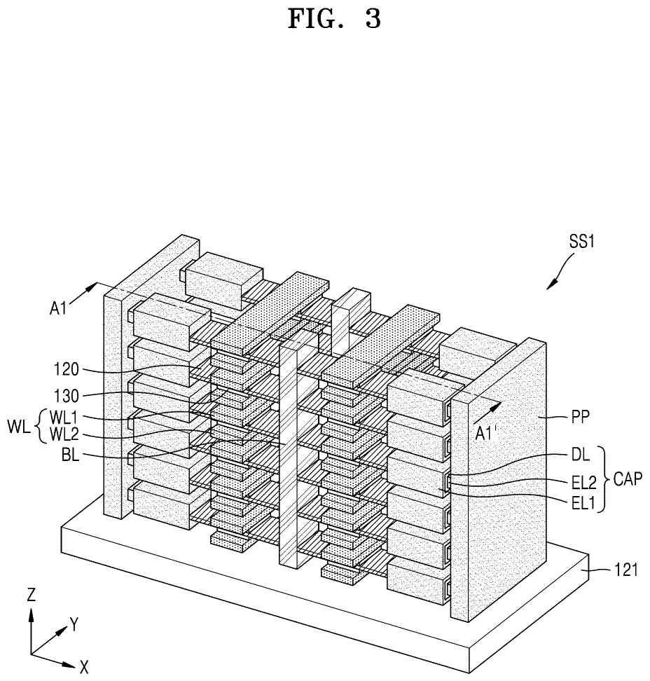

Referring to FIG. 1, a semiconductor memory device 10 may include a memory cell region MCA and a peripheral circuit region PCA at a vertical level higher than the memory cell region MCA. The terms, “level”, “height”, “vertical level”, and the like, may refer to a relative location (e.g., distance) from a reference point (e.g., from a lower surface of the separation insulating layer 121 in FIG. 3) in a vertical direction (e.g., the vertical direction Z). A farther distance from the reference point may be referred to as a higher level. A closer distance to the reference point may be referred to as a lower level.

In some embodiments, the memory cell region MCA may be a memory cell region of a dynamic random access memory (DRAM) device, and the peripheral circuit region PCA may be a core region or a peripheral circuit region of the DRAM device. For example, the peripheral circuit region PCA may include peripheral circuit transistors, each transmitting a signal and/or power to a memory cell array included in the memory cell region MCA. In some embodiments, the peripheral circuit transistors may configure various circuits, such as a command decoder, a control logic, an address buffer, a row decoder, a column decoder, a sense amplifier, and a data input/output circuit.

FIG. 1 illustrates a case in which the peripheral circuit region PCA is at a higher vertical level than the memory cell region MCA (for example, a case in which the peripheral circuit region PCA is on the memory cell region MCA), but in some embodiments, the semiconductor memory device 10 may be upside down such that the memory cell region MCA is at a higher vertical level than the peripheral circuit region PCA.

In some embodiments, the peripheral circuit region PCA and the memory cell region MCA may be formed on separate wafers, and then the peripheral circuit region PCA may be attached to the memory cell region MCA through bonding pads. In some embodiments, the peripheral circuit region PCA may be first formed on a peripheral circuit wafer, and then the memory cell region MCA may be formed on the peripheral circuit region PCA.

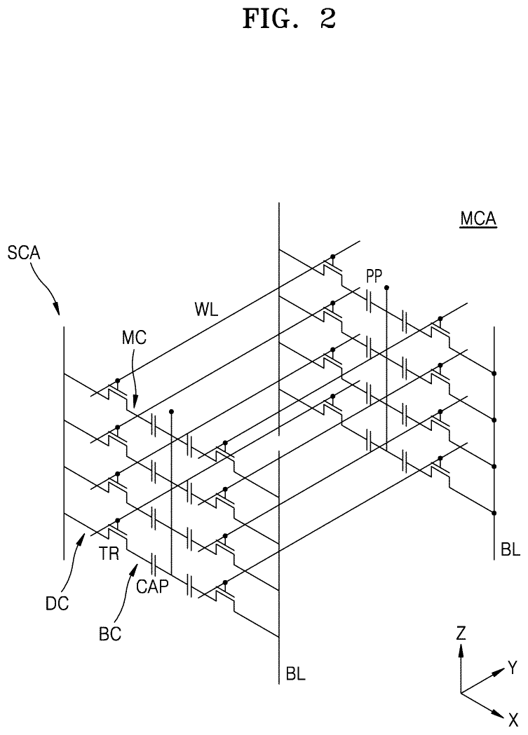

FIG. 2 is a circuit diagram illustrating the memory cell region MCA illustrated in FIG. 1.

Referring to FIG. 2, the memory cell region MCA may include a plurality of sub-cell arrays SCA. The plurality of sub-cell arrays SCA may be separated from each other in a second horizontal direction Y.

In some embodiments, the plurality of sub-cell arrays SCA may each include a plurality of bit lines BL, a plurality of word lines WL, and a plurality of memory cells MC. The plurality of memory cells MC may each include a cell transistor TR and a cell capacitor CAP (electrically) connected to the cell transistor TR. The plurality of memory cells MC may each have a one (cell) transistor-one (cell) capacitor (1T1C) structure.

In some embodiments, the plurality of word lines WL may extend in the second horizontal direction Y and may be separated from each other in a first horizontal direction X and a vertical direction Z. The plurality of bit lines BL may extend in the vertical direction Z and may be separated from each other in the first horizontal direction X and the second horizontal direction Y. The cell transistor TR may be between the word line WL and the bit line BL. The first horizontal direction X and the second horizontal direction Y intersect each other and are parallel with the lower surface (and/or the upper surface) of the separation insulating layer 121 (referring to FIG. 3). The vertical direction Z may be perpendicular to the lower surface of the separation insulating layer 121.

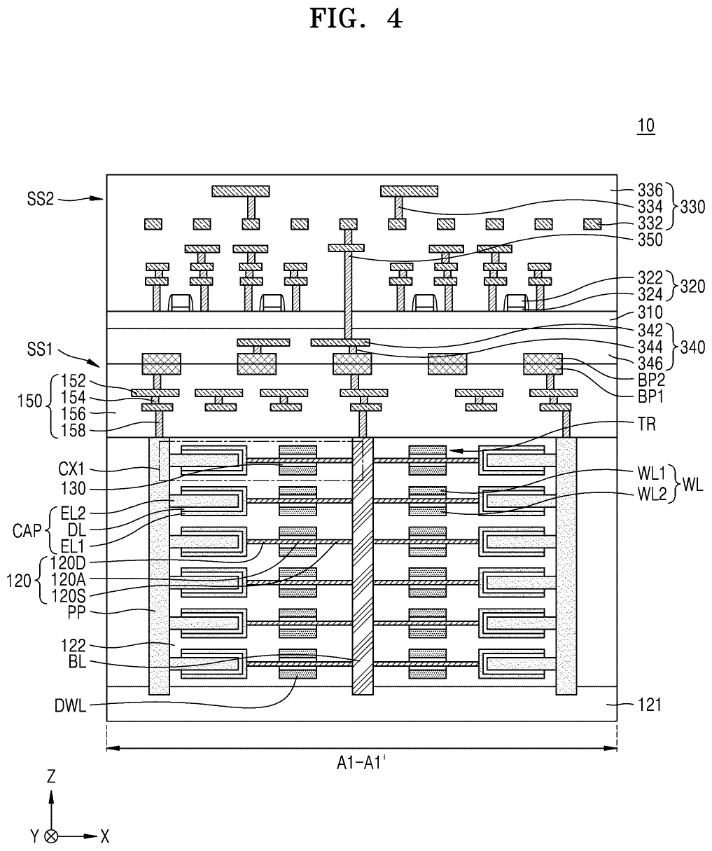

In some embodiments, a gate of the cell transistor TR may be (electrically) connected to the word line WL, and a source of the cell transistor TR (e.g., the first impurity region 120S in FIGS. 3 and 4) may be (electrically) connected to the bit line BL through a first contact DC. The cell transistor TR may be (electrically) connected to the cell capacitor CAP through a second contact BC. A drain of the cell transistor TR (e.g., the second impurity region 120D in FIGS. 3 and 4) may be (electrically) connected to a first electrode (e.g., the first electrode EL1 in FIGS. 3 and 4) of the cell capacitor CAP through the second contact BC, and a second electrode (e.g., the second electrode EL2 in FIGS. 3 and 4) of the cell capacitor CAP may be (electrically) connected to a plate electrode PP.

In some embodiments, cell transistors TRs in one sub-cell array SCA may overlap each other in the vertical direction Z. Cell capacitors CAP in one sub-cell array SCA may overlap each other in the vertical direction Z. One cell transistor TR and one cell capacitor CAP may be arranged side by side at (substantially) the same vertical level, and a plurality of memory cells MC, each including one cell transistor TR and one cell capacitor CAP, may be stacked in the vertical direction Z. A storage capacity of one sub-cell array SCA may be changed depending on the number of memory cells MC stacked in the vertical direction Z (for example, the number of cell capacitors CAP) or the number of layers of the memory cells MC stacked in the vertical direction Z (for example, the number of layers of the cell capacitors CAP).

FIG. 3 is a schematic perspective view illustrating a memory cell region of a semiconductor memory device according to an embodiment.

FIG. 4 is a cross-sectional view taken along line A1-A1′ of FIG. 3.

Referring to FIG. 3 and FIG. 4, the semiconductor memory device 10 may include a first stack structure SS1 and a second stack structure SS2, and the second stack structure SS2 may be bonded to the first stack structure SS1 by first bonding pads BP1 and second bonding pads BP2. The second stack structure SS2 may be on the first stack structure SS1.

In some embodiments, the first stack structure SS1 may include a separation insulating layer 121, a plurality of semiconductor patterns 120 arranged on the separation insulating layer 121, a plurality of bit lines BL, a plurality of word lines WL, and a plurality of cell capacitors CAP.

In some embodiments, the plurality of semiconductor patterns 120 may be on the separation insulating layer 121 to extend in the first horizontal direction X and be separated from each other in the vertical direction Z.

In some embodiments, the plurality of semiconductor patterns 120 may each include, for example, an undoped semiconductor material and/or a doped semiconductor material. In some embodiments, the plurality of semiconductor patterns 120 may each include polysilicon. In some embodiments, the plurality of semiconductor patterns 120 may each include an amorphous metal oxide, a polycrystalline metal oxide, and/or a combination of the amorphous metal oxide and the polycrystalline metal oxide. For example, the plurality of semiconductor patterns 120 may each include an In—Ga-based oxide (IGO), an In—Zn-based oxide (IZO), and/or an In—Ga—Zn-based oxide (IGZO). In some embodiments, the plurality of semiconductor patterns 120 may each include a two-dimensional (2D) material semiconductor, and for example, the 2D material semiconductor may include MoS₂, WSe₂, Graphene, Carbon Nano Tube, and/or a combination thereof.

In some embodiments, the plurality of semiconductor patterns 120 may have a line shape or a bar shape extending in the first horizontal direction X. In some embodiments, the plurality of semiconductor patterns 120 may each include a channel region 120A, and a first impurity region 120S and a second impurity region 120D, which are arranged in the first horizontal direction X with the channel region 120A therebetween. The first impurity region 120S may be (electrically) connected to the bit line BL, and the second impurity region 120D may be (electrically) connected to the cell capacitor CAP. For example, the first impurity region 120S may be between the channel region 120A and the bit line BL in the first horizontal direction X, and the second impurity region 120D may be between the channel region 120A and the cell capacitor CAP in the first horizontal direction X. Ohmic metal layers, each including a metal silicide or so on, may be further provided between the first impurity region 120S and the bit line BL, and between the second impurity region 120D and the cell capacitor CAP.

In some embodiments, the plurality of word lines WL may each include, for example, a doped semiconductor material (doped silicon, doped germanium, or so on), a conductive metal nitride (titanium nitride, tantalum nitride, or so on), a metal (tungsten, titanium, tantalum, or so on), and/or a metal-semiconductor compound (tungsten silicide, cobalt silicide, titanium silicide, or so on).

In some embodiments, the plurality of word lines WL may each have a double word line structure composed of a pair (a pair of the first word line WL1 and the second word line WL2). The plurality of word lines WL may each include a first word line WL1 and a second word line WL2 (a pair of the first word line WL1 and the second word line WL2). The first word line WL1 may be on an upper surface of the semiconductor pattern 120 (e.g., the channel region 120A) and may extend in the second horizontal direction Y. The second word line WL2 may be on a lower surface of the semiconductor pattern 120 (e.g., the channel region 120A) and may extend in the second horizontal direction Y. In this case, the first word line WL1 and the second word line WL2 may face (overlap) each other in the vertical direction Z on the channel region 120A of the semiconductor pattern 120. That is, the first word line WL1 and the second word line WL2 may be separated from each other in the vertical direction Z with the channel region 120A therebetween.

In some embodiments, the plurality of word lines WL may each have a single word line structure including only one word line arranged on the semiconductor pattern 120 (e.g., the channel region 120A). Also, the plurality of word lines WL may each have a gate all around (GAA) structure extending around (e.g., surrounding) the semiconductor pattern 120 (e.g., the channel region 120A).

In some embodiments, the plurality of word lines WL may include a plurality of dummy word lines DWL. The plurality of dummy word lines DWL may refer to the lowermost word line among the plurality of word lines WL. The plurality of dummy word lines DWL may be arranged closest to the separation insulating layer 121 in the vertical direction Z among the plurality of word lines WL. In this case, a negative voltage may be applied to the plurality of dummy word lines DWL. Although FIG. 4 illustrates that the plurality of dummy word lines DWL are arranged on a lower surface of the lowermost semiconductor pattern 120, the inventive concept is not limited thereto. For example, the plurality of dummy word lines DWL may also be arranged on an upper surface of the lowermost semiconductor pattern 120.

In some embodiments, a gate insulating layer 130 may be between the word line WL and the semiconductor pattern 120 (e.g., the channel region 120A). The gate insulating layer 130 may be on upper and lower surfaces of the semiconductor pattern 120 (e.g., the channel region 120A). The gate insulating layer 130 may include, for example, a high-k dielectric material, having a higher dielectric constant than silicon oxide, and/or a ferroelectric material. In some embodiments, the gate insulating layer 130 may include, for example, hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAlO), zirconium oxide (ZrO), zirconium silicate (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and/or lead scandium tantalum oxide (PbScTaO).

In some embodiments, the plurality of bit lines BL may extend in the vertical direction Z on the separation insulating layer 121 and be separated from each other in the second horizontal direction Y. The plurality of bit lines BL may extend in (e.g., pass through) a part of the separation insulating layer 121 in the vertical direction Z. The plurality of bit lines BL may, include, for example, a doped semiconductor material, a conductive metal nitride, a metal, and/or a metal-semiconductor compound.

In some embodiments, the plurality of cell capacitors CAP may each include a first electrode EL1, a capacitor dielectric layer DL, and a second electrode EL2. The first electrode EL1 may extend in the first horizontal direction X, and ends of the first electrode EL1 may be separated from each other in the vertical direction Z. The first electrode EL1 may have a space (e.g., an internal space) (not illustrated) extending in the first horizontal direction X, and the internal space may be (at least partially) filled with the capacitor dielectric layer DL and the second electrode EL2. For example, the first electrode EL1 may be partially recessed in the first horizontal direction X to form the (internal) space therein. For example, (in a cross-sectional view) the first electrode EL1 may have a cup shape rotated 90 degrees.

In some embodiments, the capacitor dielectric layer DL may include, for example, a high-k dielectric material, having a dielectric constant higher than silicon oxide, and/or a ferroelectric material. In some embodiments, the capacitor dielectric layer DL may include, for example, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and/or lead scandium tantalum oxide (PbScTaO).

In some embodiments, the second electrode EL2 may (at least partially) fill the internal space of the first electrode EL1, and the capacitor dielectric layer DL may be between the internal space of the first electrode EL1 and the second electrode EL2. In some embodiments, the capacitor dielectric layer DL may extend around the second electrode EL2, and the first electrode EL1 may extend around the capacitor dielectric layer DL. For example, in a cross-sectional view, the capacitor dielectric layer DL may be on three (3) surfaces of the second electrode EL2 that has a rectangular shape, and the first electrode EL1 may be on three (3) surfaces of the capacitor dielectric layer DL. In some embodiments, (in a cross-sectional view) the capacitor dielectric layer DL may have a cup shape rotated 90 degrees.

In some embodiments, the first electrode EL1 and the second electrode EL2 may each include, for example, a doped semiconductor material, a conductive metal nitride such as titanium nitride, tantalum nitride, niobium nitride, and/or tungsten nitride, a metal such as ruthenium, iridium, titanium, and/or tantalum, and/or a conductive metal oxide such as iridium oxide and/or niobium oxide.

In some embodiments, the plate electrode PP may be on one side of the cell capacitor CAP to extend in the vertical direction Z and the second horizontal direction Y. The plate electrode PP may be on the separation insulating layer 121 to extend in the vertical direction Z and the second horizontal direction Y. The plate electrode PP may extend in (e.g., pass through) a part of the separation insulating layer 121 in the vertical direction Z.

In some embodiments, the second electrode EL2 of the cell capacitor CAP may be (electrically) connected to the plate electrode PP, and, for example, a plurality of second electrodes EL2 separated from each other in the vertical direction Z and a plurality of second electrodes EL2 separated from each other in the second horizontal direction Y may be commonly (electrically) connected to the plate electrode PP.

In some embodiments, mold insulating layers 122 may be respectively between two adjacent semiconductor patterns 120 separated from each other in the vertical direction Z, between two adjacent word lines WL (e.g., two adjacent pairs of first word line WL1 and second word line WL2) separated from each other in the vertical direction Z, and between two adjacent first electrodes EL1 separated from each other in the vertical direction Z. Also, the mold insulating layers 122 may each be between (two) bit lines BL (e.g., adjacent bit lines BL) separated from each other in the second horizontal direction Y.

In some embodiments, the mold insulation layers 122 may each include, for example, silicon oxide, silicon oxynitride, silicon nitride, carbon-containing silicon oxide, carbon-containing silicon oxynitride, carbon-containing silicon nitride, and/or a combination thereof. In some embodiments, the mold insulation layers 122 may each include a plurality of insulating layers. Here, insulating material layers respectively formed between the plurality of bit lines BL, between the plurality of word lines WL, between the plurality of semiconductor patterns 120, and between the plurality of cell capacitors CAP according to a manufacturing process used to form a three-dimensional structure may be collectively referred to as the mold insulation layers 122.

In some embodiments, the separation insulation layer 121 may include, for example, silicon oxide, silicon oxynitride, silicon nitride, carbon-containing silicon oxide, carbon-containing silicon oxynitride, carbon-containing silicon nitride, and/or a combination thereof. An upper surface of the separation insulating layer 121 may be in contact with a lower surface of the mold insulating layer 122. Although FIG. 4 illustrates a boundary line between the separation insulating layer 121 and the mold insulating layer 122, the boundary line between the separation insulating layer 121 and the mold insulating layer 122 may not be formed. For example, the separation insulating layer 121 and the mold insulating layer 122 may form an integrated structure without a (visible) boundary therebetween.

In some embodiments, the plurality of bit lines BL may extend in (e.g., pass through) a part of the separation insulating layer 121 in the vertical direction Z. Vertical levels of lower surfaces of the plurality of bit lines BL may be lower than a vertical level of an upper surface of the separation insulating layer 121. The plate electrode PP may extend in (e.g., pass through) a part of the separation insulating layer 121 in the vertical direction Z. A vertical level of a lower surface of the plate electrode PP may be lower than the vertical level of the upper surface of the separation insulating layer 121. The separation insulating layer 121 may electrically insulate between the plurality of bit lines BL, between a plurality of plate electrodes PP, and between each of the plurality of bit lines BL and each of the plurality of plate electrodes PP.

In a comparative example, a separate insulating layer has to be formed between a bit line and a substrate to insulate the bit line from the substrate in contact with the bit line, and accordingly, there is a problem in that process difficulty of a semiconductor memory device increases, causing an increase in manufacturing costs of the semiconductor memory device and a decrease in reliability of the semiconductor memory device.

In the semiconductor memory device 10 according to the inventive concept, the plurality of bit lines BL are in direct contact with the separation insulating layer 121 instead of a substrate, and thus, a process of forming separate insulation layers for insulating the plurality of bit lines BL from the substrate may be omitted. Therefore, by omitting a process of forming separate insulating layers between the plurality of bit lines BL and the substrate, process difficulty of the semiconductor memory device 10 may be reduced, and thus, manufacturing costs of the semiconductor memory device 10 may be reduced, and reliability of the semiconductor memory device 10 may be increased.

Also, as one end of each of the plurality of bit lines BL and one end of each of the plurality of plate electrodes PP are in contact with the separation insulating layer 121, there may be an effect of preventing bridges (defects) between the plurality of bit lines BL, between the plurality of plate electrodes PP, and between the plurality of bit line BL and the plurality of plate electrodes PP.

In some embodiments, the first stack structure SS1 may include an upper wiring structure 150. The upper wiring structure 150 may include a wiring layer 152, a via 154, and an insulating layer 156. The upper wiring structure 150 may further include a contact 158 (electrically) connected to the bit line BL, the word line WL, and the plate electrode PP. Also, the first bonding pad BP1 on the same plane as an uppermost surface of the insulating layer 156 may be formed over the upper wiring structure 150 (e.g., over the wiring layer 152, the via 154, and the contact 158). For example, an upper surface of the first bonding pad BP1 and the uppermost surface of the insulating layer 156 may be at the same vertical level.

In some embodiments, the second stack structure SS2 may include a second substrate 310, a peripheral circuit transistor 320 on the second substrate 310, a front wiring structure 330, which covers (e.g., overlaps in the vertical direction Z) the peripheral circuit transistor 320, on an upper surface of the second substrate 310, and a rear wiring structure 340 on a lower surface of the second substrate 310. The front wiring structure 330 may include a wiring layer 332, a via 334, and an insulating layer 336, and the rear wiring structure 340 may include a wiring layer 342, a via 344, and an insulating layer 346.

In some embodiments, the rear wiring structure 340 may include the second bonding pad BP2 on the same plane as a lower surface of the insulating layer 346, and the first stack structure SS1 may be bonded to the second stack structure SS2 as the second bonding pad BP1 is connected to the first bonding pad BP2. For example, a lower surface of the second bonding pad BP2 and the lower surface of the insulating layer 346 may be at the same vertical level. In some embodiments, the first stack structure SS1 may be bonded to the second stack structure SS2 through copper-oxide hybrid bonding. In some embodiments, the second bonding pad BP2 and the first bonding pad BP1 may each include copper and/or a copper alloy. A boundary line between the insulating layer 156 of the upper wiring structure 150 and the insulating layer 346 of the rear wiring structure 340 may flatly extend and may be on the same plane (at the same vertical level) as a boundary line between the second bonding pad BP2 and the first bonding pad BP1.

In some embodiments, the peripheral circuit transistor 320 may include a gate electrode 322 and a gate insulating layer 324, which are arranged over (in/on) an active region of the second substrate 310. In some embodiments, the peripheral circuit transistor 320 may include sense amplifiers, and the sense amplifiers may be (electrically) connected to bit lines BL included in the first stack structure SS1. Also, the peripheral circuit transistor 320 may include sub-word line drivers, and the sub-word line drivers may be (electrically) connected to word lines WL included in the first stack structure SS1.

In some embodiments, the second stack structure SS2 may further include a through-via 350 extending in (e.g., passing through) the second substrate 310. The through-via 350 may (electrically) connect the wiring layer 332 included in the front wiring structure 330 to the wiring layer 342 included in the rear wiring structure 340. Also, the wiring layer 342 included in the rear wiring structure 340 may be (electrically) connected to the wiring layer 152 included in the upper wiring structure 150 through the second bonding pad BP2 and the first bonding pad BP1.

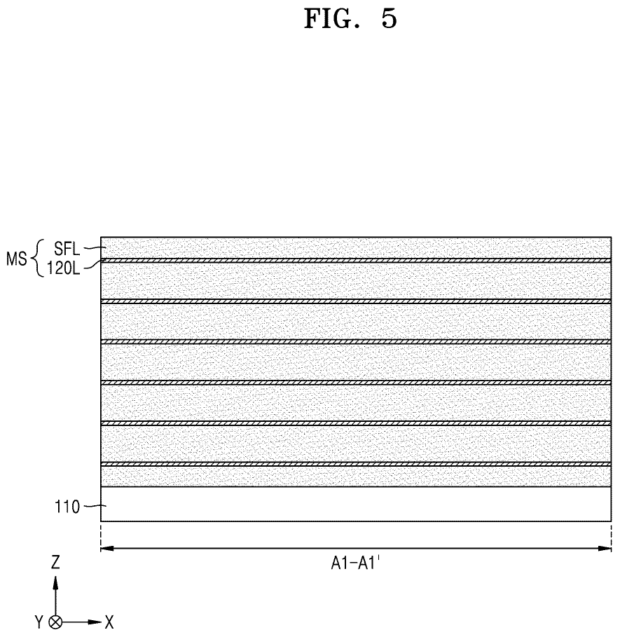

FIGS. 5 to 12 are cross-sectional views illustrating a method of manufacturing a semiconductor memory device, according to an embodiment and are cross-sectional views taken along line A1-A1′ of FIG. 3. In FIGS. 5 to 12, the same reference numerals as in FIGS. 3 and 4 represent the same components unless clearly described otherwise, and redundant descriptions thereof may be omitted herein.

Referring to FIG. 5, a plurality of sacrificial mold layers SFL and a plurality of semiconductor layers 120L may be alternately and sequentially formed on a first substrate 110 to form a mold stack MS.

In some embodiments, the first substrate 110 may include, for example, Si, Ge, and/or SiGe. In some embodiments, the first substrate 110 may include a silicon-on-insulator (SOI) substrate or a germanium-on-insulator (GeOI) substrate.

In some embodiments, the plurality of sacrificial mold layers SFL and the plurality of semiconductor layers 120L may each include a material having an etching selectivity with respect to each other. For example, the plurality of sacrificial mold layers SFL and the plurality of semiconductor layer 120L may each include a single crystal layer of a group IV semiconductor, a group II-VI compound semiconductor, and/or a group III-V compound semiconductor, and the sacrificial mold layer SFL and the semiconductor layer 120L may include different materials. In one embodiment, the plurality of sacrificial mold layers SFL may each include SiGe, and the plurality of semiconductor layers 120L may each include single crystal silicon. The plurality of sacrificial mold layers SFL and the plurality of semiconductor layers 120L may each have a thickness of several tens of nanometers (nm).

In some embodiments, the plurality of sacrificial mold layers SFL and the plurality of semiconductor layers 120L may be formed through an epitaxy process. For example, the epitaxy process may be a vapor-phase epitaxy (VPE) process, a chemical vapor deposition (CVD) process such as an ultra-high vacuum CVD (UHV-CVD) process, a molecular beam epitaxy process, or a combination thereof. In the epitaxy process, a liquid or gaseous precursor may be used as a precursor required to form the plurality of sacrificial mold layers SFL and the plurality of semiconductor layers 120L.

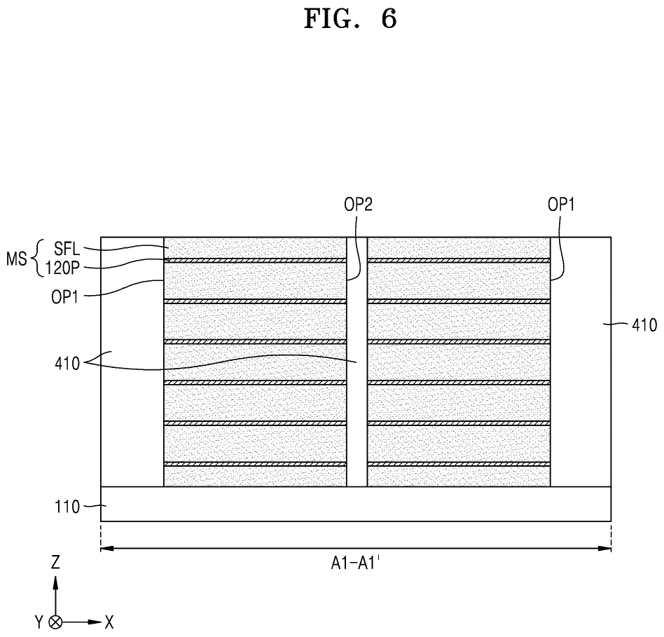

Referring to FIG. 6, a mask pattern (not illustrated) may be formed on the mold stack MS, and parts of the mold stack MS may be removed by using the mask pattern as an etching mask to form a first opening OP1 and a second opening OP2. Thereafter, a separation insulating layer 410 may be formed in the first opening OP1 and the second opening OP2. The first openings OP1 and the second openings OP2 may be alternately arranged in the first horizontal direction X. For example, one of the second openings OP2 may be between two adjacent first openings OP1 in the first horizontal direction X. For example, a portion of the mold stack MS between two adjacent first openings OP1 in the first horizontal direction X may be separated into two stacks by the second opening OP2 and the separation insulating layer 410 therein. The two separated stacks of the mold stack MS may have (substantially) the same width in the first horizontal direction X.

The semiconductor layers 120L of the mold stack MS may be patterned (e.g., separated) by the first opening OP1 and the second opening OP2 (and the separation insulating layer 410 therein) to form a plurality of preliminary semiconductor patterns 120P. For example, the plurality of preliminary semiconductor patterns 120P may include a pair of preliminary semiconductor patterns 120P at the same vertical level, and the pair of preliminary semiconductor patterns 120P may be spaced apart from each other in the first horizontal direction X by the second opening OP2 and the separation insulating layer 410 therein.

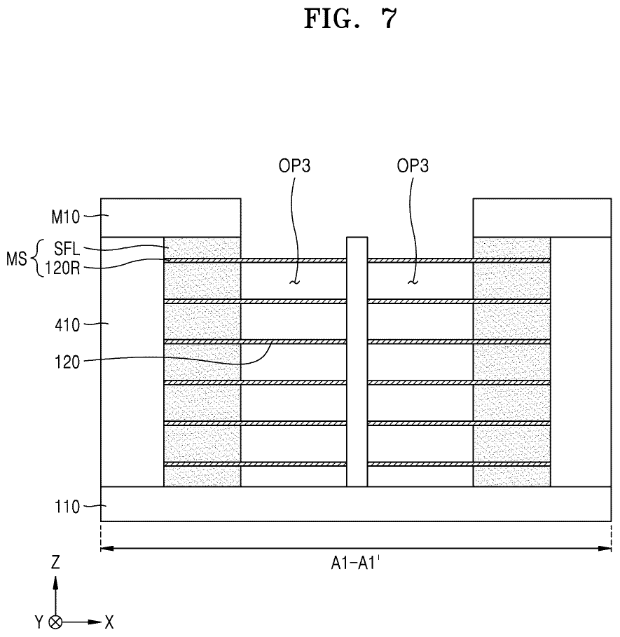

Referring to FIG. 7, part of the sacrificial mold layer SFL may be removed to form a third opening OP3 between the plurality of preliminary semiconductor patterns 120P (in the vertical direction Z).

In some embodiments, a mask pattern M10 may be formed on the mold stack MS, part of the sacrificial mold layer SFL that is not covered (not overlapped in the vertical direction Z) by the mask pattern M10 may be removed, and parts of the sacrificial mold layer SFL that vertically overlap the mask pattern M10 may remain without being removed. In some embodiments, the third opening OP3 may be between the remaining sacrificial mold layer SFL and the separation insulating layer 410 in the second opening OP2 (in the first horizontal direction X). Here, part of the preliminary semiconductor pattern 120P covered (overlapped in the vertical direction Z) by the sacrificial mold layer SFL may be referred to as a residual pattern 120R. A part of the preliminary semiconductor pattern 120P that is not covered (not overlapped in the vertical direction Z) by the sacrificial mold layer SFL may be referred to as the semiconductor pattern 120. For example, the semiconductor pattern 120 may be exposed by the third opening OP3 without the sacrificial mold layer SFL thereon. The mask pattern M10 may be on a structure in which the residual pattern 120R and the sacrificial mold layer SFL are alternately stacked. For example, the mask pattern M10 may overlap the residual pattern 120R in the vertical direction Z.

In some embodiments, a process of removing (a portion of) the sacrificial mold layer SFL (e.g., a process of forming the third opening OP3) may be a wet etching process or a pull-back process. For example, the process of removing the sacrificial mold layer SFL may be an etching process using an etching selectivity between the sacrificial mold layer SFL and the preliminary semiconductor pattern 120P. For example, in the wet etching process or the pull-back process, an etching speed of the plurality of preliminary semiconductor patterns 120P may be relatively low, and an etching speed of the sacrificial mold layer SFL may be relatively high.

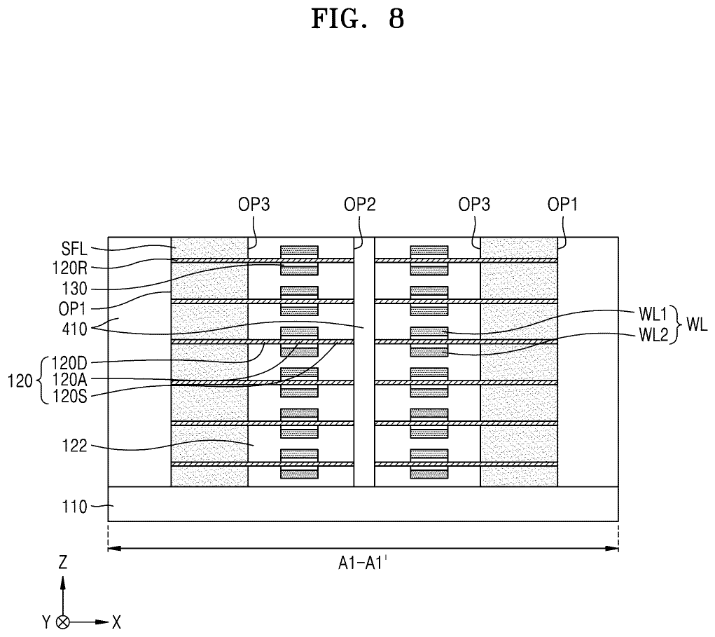

Referring to FIG. 8, the gate insulating layer 130 and the word line WL may be sequentially formed on an upper surface and a lower surface of each of the plurality of semiconductor patterns 120 in the third opening OP3.

In some embodiments, the gate insulating layer 130 may be conformally arranged on the lower surface and the upper surface of each of the plurality of semiconductor patterns 120, and the word line WL may extend in the second horizontal direction Y on the gate insulating layer 130. For example, the first word line WL1 may be on the upper surface of the semiconductor pattern 120, and the second word line WL2 may be on the lower surface of the semiconductor pattern 120.

In some embodiments, the gate insulating layer 130 and the word line WL at both end regions (for example, both (opposite) end regions in the first horizontal direction X) of each of the plurality of semiconductor patterns 120 may be partially removed in the third opening OP3. In other embodiments, a protective layer (not illustrated) covering both end regions (e.g., opposite end regions in the first horizontal direction X or non-central regions) of each of the plurality of semiconductor patterns 120 may be first formed in the third opening OP3, the gate insulating layer 130 and the word line WL may be formed on an upper surface and a lower surface of a central portion (e.g., a central region in the first horizontal direction X) of each of the plurality of semiconductor patterns 120, and then the protective layer may be removed such that both end regions (e.g., opposite end regions in the first horizontal direction X or non-central regions) of each of the plurality of semiconductor patterns 120 may be exposed again without being covered by the gate insulating layer 130 and the word line WL. For example, a central region of the semiconductor pattern 120 may be covered (overlapped in the vertical direction Z) by the gate insulating layer 130 and the word line WL (the first word line WL1 and the second word line WL2), and opposite end regions (non-central regions) in the first horizontal direction X may not be covered (not be overlapped in the vertical direction Z) by the gate insulating layer 130 and the word line WL (the first word line WL1 and the second word line WL2).

Thereafter, the first impurity region 120S and the second impurity region 120D may be formed (by impurity doping process, such as implantation and diffusion). The first impurity region 120S and the second impurity region 120D may be formed at both end regions (e.g., opposite end regions in the first horizontal direction X) of each of the plurality of semiconductor patterns 120 exposed by partial removing of the gate insulating layer 130 and the word line WL. The channel region 120A may be formed between the first impurity region 120S and the second impurity region 120D (in the first horizontal direction X). For example, the first impurity region 120S may be between the (remaining) sacrificial mold layer SFL and the channel region 120A (in the first horizontal direction X), and the second impurity region 120D may be between the separation insulating layer 410 in the second opening OP2 and the channel region 120A (in the first horizontal direction X).

Thereafter, the mold insulating layer 122 may be formed in (formed to at least partially fill the inside of) the third opening OP3. In some embodiments, the mold insulating layer 122 may be between two word lines WL adjacent in the vertical direction Z and between end regions (non-central regions) of adjacent two semiconductor patterns 120 in the vertical direction Z.

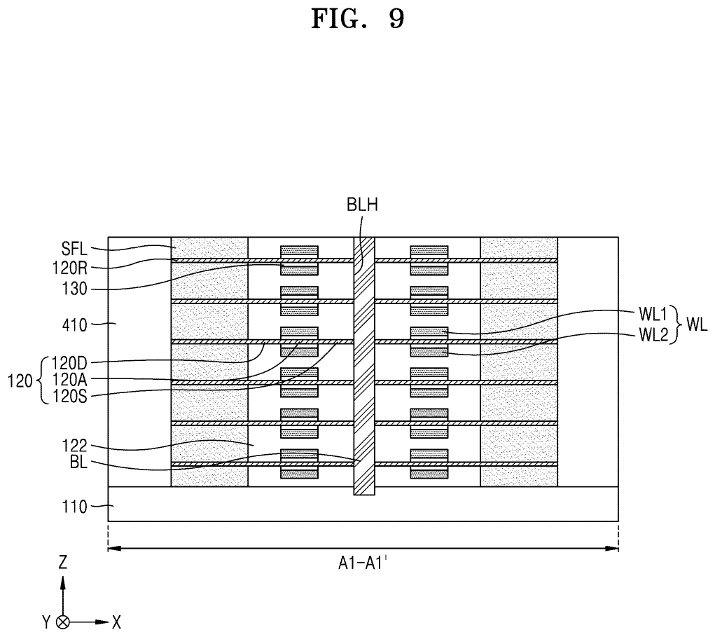

Referring to FIG. 9, a bit line opening BLH may be formed by removing part of the separation insulating layer 410 (the separation insulating layer 410 in the second opening OP2), and the bit line BL may be formed in the bit line opening BLH. In this case, the bit line opening BLH may extend in (e.g., penetrate) part of the first substrate 110. Therefore, the bit line BL may extend in (e.g., pass through) part of the first substrate 110.

In some embodiments, two semiconductor patterns 120 may be separated from each other in the first horizontal direction X with the bit line BL therebetween, and a first sidewall of the bit line BL may be in contact with the first impurity region 120S of one semiconductor pattern 120, and a second sidewall of the bit line BL may be in contact with the first impurity region 120S of another semiconductor pattern 120. That is, two semiconductor patterns 120 (two first impurity region 120S) at the same vertical level may be (electrically) connected to the bit line BL, but the inventive concept is not limited thereto.

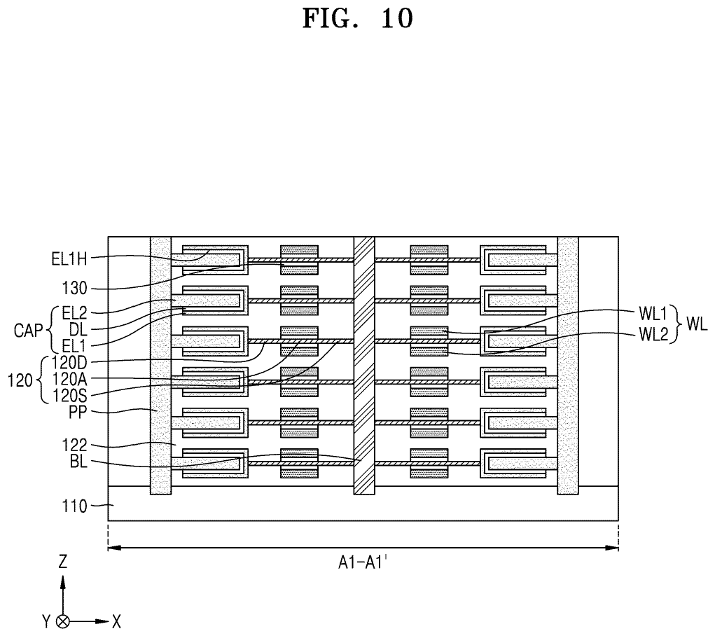

Referring to FIG. 10, the sacrificial mold layer SFL and the residual pattern 120R may be removed, and the cell capacitor CAP may be formed at a position where the sacrificial mold layer SFL and the residual pattern 120R are removed.

In some embodiments, the cell capacitor CAP may include the first electrode EL1, the capacitor dielectric layer DL, and the second electrode EL2. The first electrode EL1 may be (electrically) connected to the second impurity region 120D of the semiconductor pattern 120 and may have an internal space EL1H extending in the first horizontal direction X. The capacitor dielectric layer DL may be (conformally) arranged in the internal space EL1H, and the internal space EL1H may be (at least partially) filled with the second electrode EL2.

Thereafter, the plate electrode PP may be formed to be (electrically) connected to the second electrode EL2 and to extend in the second horizontal direction Y. In this case, the plate electrode PP may extend in (e.g., pass through) part of the first substrate 110 in the vertical direction Z.

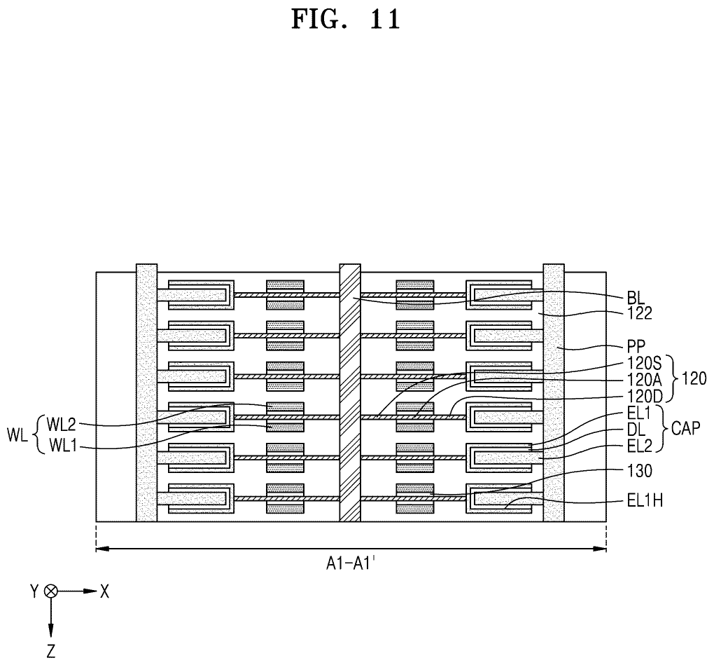

Referring to FIG. 11, after a result of FIG. 10 is turned over, the first substrate 110 (see FIG. 10) may be removed. As the first substrate 110 is removed, part of the bit line BL and part of the plate electrode PP may be exposed. Also, one surface of the mold insulating layer 122 may be exposed.

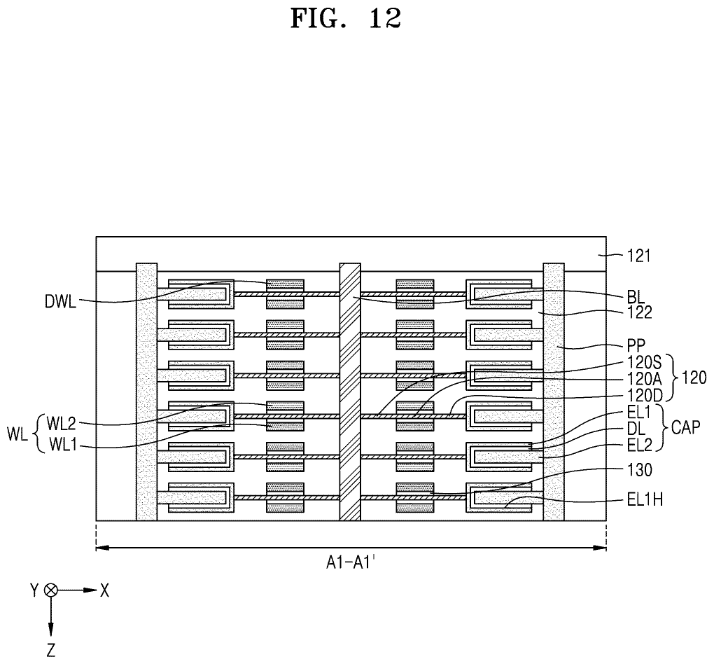

Referring to FIG. 12, the separation insulating layer 121 may be formed in the result of FIG. 11. The separation insulating layer 121 may be on (e.g., may cover) the exposed part of bit line BL and the exposed part of the plate electrode PP. Also, the separation insulating layer 121 may be on (e.g., may cover) the exposed surface (one surface) of the mold insulating layer 122. The separation insulating layer 121 may electrically insulate (may separate) the plurality of bit lines BL from each other, the plurality of plate electrodes PP from each other, and the plurality of bit lines BL from the plurality of plate electrodes PP. In this process, the plurality of dummy word lines DWL may be formed. The plurality of dummy word lines DWL may be closest one to the separation insulating layer 121 in the vertical direction Z among the plurality of word lines WL.

Referring to FIG. 4 again, after a result of FIG. 12 is turned over, an upper wiring structure 150 may be formed. The upper wiring structure 150 may include the wiring layer 152, the via 154, an insulation layer 156, and the contact 158. For example, the contact 158 may be (electrically) connected to the bit line BL, the word line WL, and the plate electrode PP. Thereafter, the first bonding pad BP1 may be formed over (in/on) the upper wiring structure 150 to be on the same plane as an uppermost surface of the insulating layer 156.

Thereafter, the second stack structure SS2 may be provided on the first stack structure SS1. In some embodiments, the second stack structure SS2 may include the second substrate 310, the peripheral circuit transistor 320 on the second substrate 310, the front wiring structure 330 provided on an upper surface of the second substrate 310 to cover (overlap in the vertical direction Z) the peripheral circuit transistor 320, and the rear wiring structure 340 on a lower surface of the second substrate 310.

In some embodiments, the peripheral circuit transistor 320 may be formed on a first surface (or an upper surface) of the second substrate 310, the front wiring structure 330 may be formed on the first surface of the second substrate 310, a carrier substrate may be attached onto the front wiring structure 330, and then a second surface (or a lower surface) of the second substrate 310 may be ground to thin the second substrate 310. Thereafter, the rear wiring structure 340 and the second bonding pad (BP2) may be formed on the second surface of the second substrate 310, and accordingly, the second stack structure SS2 may be completed (formed).

Thereafter, the second stack structure SS2 may be bonded to the first stack structure SS1, and in this case, the first bonding pad BP1 of the first stack structure SS1 may be bonded to the second bonding pad BP2 of the second stack structure SS2, and an upper surface of the insulation layer 156 may be bonded to a lower surface of the insulation layer 346.

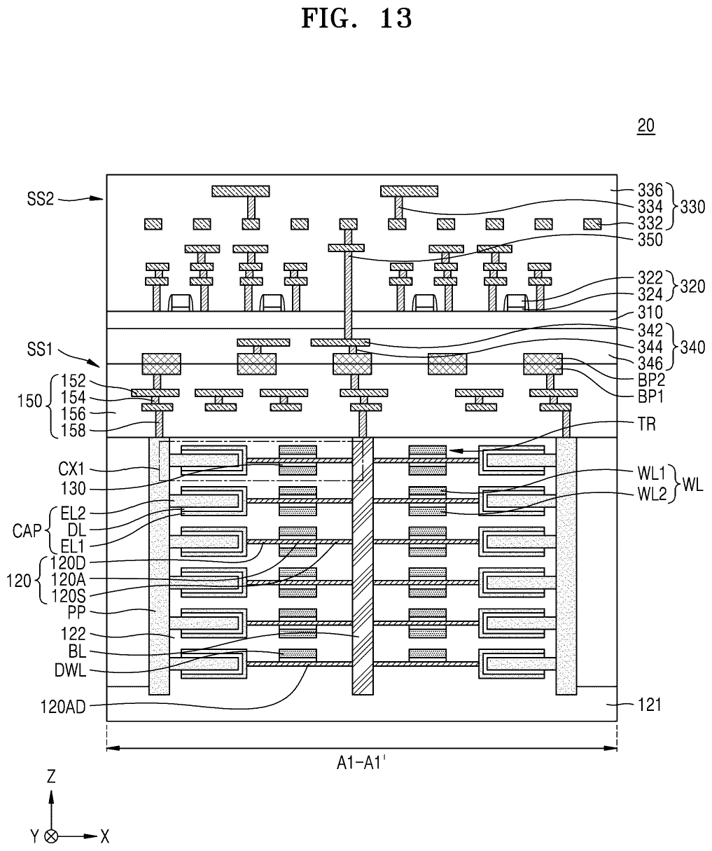

FIG. 13 is a cross-sectional view of a semiconductor memory device according to an embodiment and is a cross-sectional view taken along line A1-A1′ of FIG. 3. In FIG. 13, the same reference numerals as in FIGS. 3 and 4 represent the same members unless clearly described otherwise, and redundant descriptions thereof may be omitted herein.

Referring to FIG. 13, a semiconductor memory device 20 of the inventive concept may include the separation insulating layer 121 and a dummy semiconductor pattern 120AD.

In some embodiments, the plurality of semiconductor patterns 120 may include a plurality of dummy semiconductor patterns 120AD. The plurality of dummy semiconductor patterns 120AD may refer to the lowermost semiconductor pattern(s) among the plurality of semiconductor patterns 120. The plurality of dummy semiconductor patterns 120AD may be semiconductor patterns that are arranged closest to the separation insulating layer 121 in the vertical direction Z among the plurality of semiconductor patterns 120. The plurality of dummy word lines DWL may be on upper surfaces of the plurality of dummy semiconductor patterns 120AD. In this case, a negative voltage may be applied to the plurality of dummy word lines DWL.

In some embodiments, the separation insulating layer 121 may include, for example, silicon oxide, silicon oxynitride, silicon nitride, carbon-containing silicon oxide, carbon-containing silicon oxynitride, carbon-containing silicon nitride, and/or a combination thereof. An upper surface of the separation insulating layer 121 may be in contact with a lower surface of each of the plurality of dummy semiconductor patterns 120AD. The separation insulating layer 121 may be in contact with a lower surface of the cell capacitor CAP. In this case, the separation insulating layer 121 may include a different material from the mold insulating layer 122. When the separation insulating layer 121 includes a different material from the mold insulating layer 122, different insulating materials may be respectively on an upper surface and a lower surface of each of the dummy semiconductor pattern 120AD.

In some embodiments, the plurality of bit lines BL may extend in (e.g., pass through) part of the separation insulating layer 121 in the vertical direction Z. A vertical level of a lower surface of each of the plurality of bit lines BL may be lower than a vertical level of an upper surface of the separation insulating layer 121. The plate electrode PP may extend in (e.g., pass through) part of the separation insulating layer 121 in the vertical direction Z. A vertical level of a lower surface of the plate electrode PP may be lower than a vertical level of the upper surface of the separation insulating layer 121. The separation insulating layer 121 may electrically insulate (may separate) the plurality of bit lines BL from each other, the plurality of plate electrodes PP from each other, and between the plurality of bit lines BL and the plurality of plate electrodes PP.

In a comparative example, a separate insulating layer has to be formed between a bit line and a substrate to insulate the bit line from the substrate in contact with the bit line, and accordingly, there is a problem in that process difficulty of a semiconductor memory device increases, causing an increase in manufacturing costs of the semiconductor memory device and a decrease in reliability of the semiconductor memory device.

In the semiconductor memory device 20 according to the inventive concept, the plurality of bit lines BL are in direct contact with the separation insulating layer 121 instead of a substrate, and thus, a process of forming separate insulation layers for insulating the plurality of bit lines BL from the substrate may be omitted. Therefore, by omitting a process of forming separate insulating layers between the plurality of bit lines BL and the substrate, process difficulty of the semiconductor memory device 20 may be reduced, and thus, manufacturing costs of the semiconductor memory device 20 may be reduced, and reliability of the semiconductor memory device 20 may be increased.

Also, one end of each of the plurality of bit lines BL and one end of each of the plurality of plate electrodes PP are in contact with the separation insulating layer 121, there is an effect of preventing bridges between the plurality of bit lines BL, between the plurality of plate electrodes PP, and between the plurality of bit line BL and the plurality of plate electrodes PP.

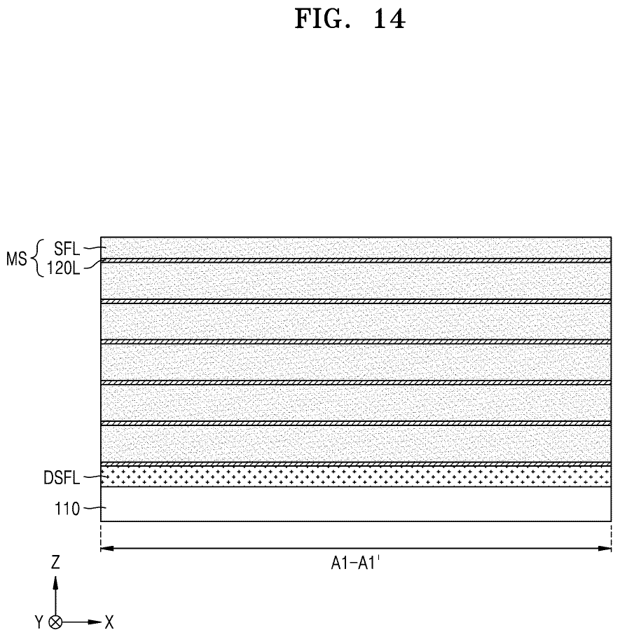

FIGS. 14 to 21 are cross-sectional views illustrating a method of manufacturing a semiconductor memory device according to an embodiment and are cross-sectional views taken along line A1-A1′ of FIG. 13. In FIGS. 14 to 21, the same reference numerals as in FIGS. 3 to 12 represent the same components unless clearly described otherwise, and redundant descriptions thereof may be omitted herein.

Referring to FIG. 14, a plurality of sacrificial mold layers SFL and a plurality of semiconductor layers 120L may be alternately and sequentially formed on a first substrate 110 to form the mold stack MS.

In some embodiments, the first substrate 110 may include, for example, Si, Ge, and/or SiGe. In some embodiments, the first substrate 110 may include an SOI substrate or a GeOI substrate.

In this case, the plurality of sacrificial mold layers SFL may include a dummy sacrificial mold layer DSFL. The dummy sacrificial mold layer DSFL may be formed on the first substrate 110. The dummy sacrificial mold layer DSFL may refer to the lowermost sacrificial mold layer among the plurality of sacrificial mold layers SFL.

In some embodiments, the plurality of sacrificial mold layers SFL and the plurality of semiconductor layer 120L may each include a material having an etching selectivity with respect to each other. For example, the plurality of sacrificial mold layers SFL and the plurality of semiconductor layers 120L may each include a single crystal layer of a group IV semiconductor, a group II-VI compound semiconductor, and/or a group III-V compound semiconductor, and each of the plurality of sacrificial mold layers SFL and each of the plurality of semiconductor layers 120L may include different materials. In one embodiment, the plurality of sacrificial mold layers SFL may each include SiGe, and the plurality of semiconductor layers 120L may each include single crystal silicon. The plurality of sacrificial mold layers SFL and the plurality of semiconductor layers 120L may each have a thickness of several tens of nm.

In some embodiments, the dummy sacrificial mold layer DSFL and the sacrificial mold layer SFL may have an etching selectivity with respect to each other. Concentration ratios of silicon and germanium included in the dummy sacrificial mold layer DSFL and the sacrificial mold layer SFL may be different from each other. For example, the sacrificial mold layer SFL may have a concentration ratio of Six1Gey1, and the dummy sacrificial mold layer DSFL may have a concentration ratio of Six1Gey2. Also, the sacrificial mold layer SFL may have a concentration ratio of Six1Gey1, and the dummy sacrificial mold layer DSFL may have a concentration ratio of Six2Gey1. Also, the sacrificial mold layer SFL may have a concentration ratio of Six1Gey1, and the dummy sacrificial mold layer DSFL may have a concentration ratio of Six2Gey2 (wherein x1 and x2 are different real numbers, and y1 and y2 are different real numbers).

In some embodiments, the dummy sacrificial mold layer DSFL, the plurality of sacrificial mold layers SFL, and the plurality of semiconductor layers 120L may be formed through an epitaxy process. For example, the epitaxy process may be a VPE process, a CVD process such as an UHV-CVD process, a molecular beam epitaxy process, or a combination thereof. In the epitaxy process, a liquid or gaseous precursor may be used as a precursor required to form the dummy sacrificial mold layer DSFL, the plurality of sacrificial mold layers SFL, and the plurality of semiconductor layers 120L.

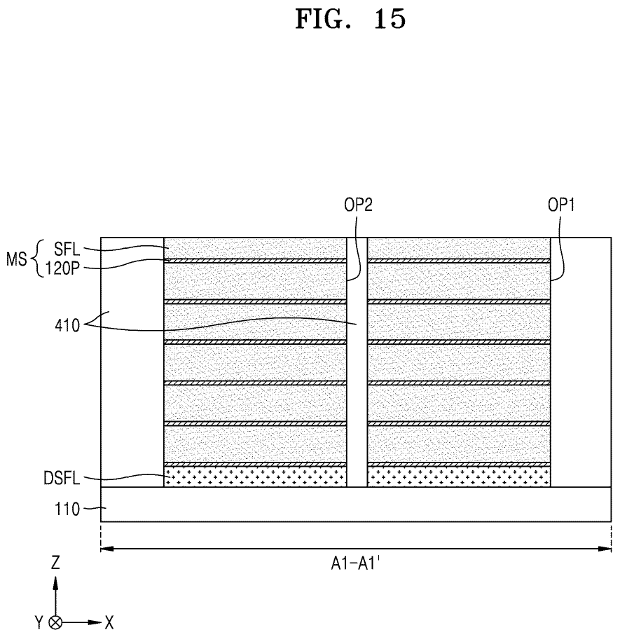

Referring to FIG. 15, a mask pattern (not illustrated) may be formed on a mold stack MS, and part of the mold stack MS may be removed by using the mask pattern as an etching mask to form a first opening OP1 and a second opening OP2. Thereafter, a separation insulating layer 410 may be formed in the first opening OP1 and the second opening OP2.

In some embodiments, the semiconductor layers 120L of the mold stack MS may be patterned (e.g., separated) by the first opening OP1 and the second opening OP2 (an the separation insulating layer 410 therein) to form a plurality of preliminary semiconductor patterns 120P.

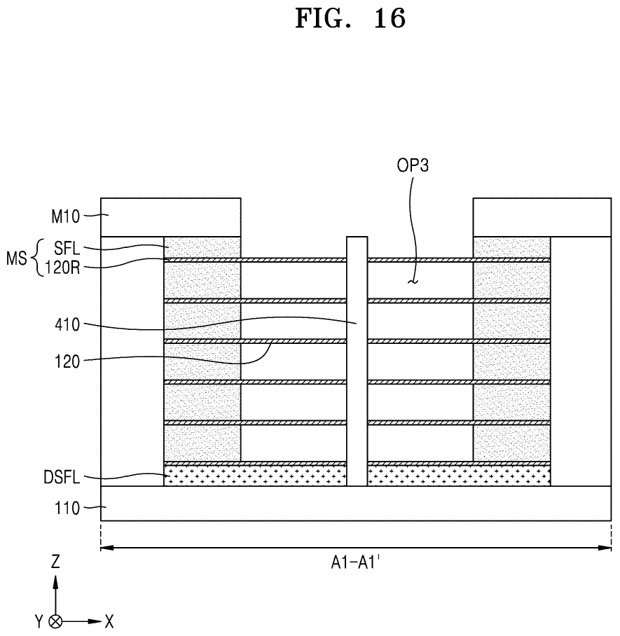

Referring to FIG. 16, the plurality of sacrificial mold layers SFL may be partially removed to form the third opening OP3 between the plurality of preliminary semiconductor patterns 120P.

In some embodiments, a mask pattern M10 may be formed on the mold stack MS, part of the sacrificial mold layer SFL that is not covered (not overlapped in the vertical direction Z) by the mask pattern M10 may be removed, and parts of the sacrificial mold layer SFL that vertically overlap the mask pattern M10 may remain without being removed. Here, part of the preliminary semiconductor pattern 120P covered (overlapped in the vertical direction Z) by the sacrificial mold layer SFL is referred to as a residual pattern 120R. A part of the preliminary semiconductor pattern 120P exposed by the third opening OP3 may be referred to as the semiconductor pattern 120. The mask pattern M10 may be on (may overlap in the vertical direction Z) a structure in which the residual pattern 120R and the sacrificial mold layer SFL are alternately stacked. In this case, the lowermost dummy sacrificial mold layer DSFL may remain without being removed due to an etching selectivity of the dummy sacrificial mold layer DSFL and the sacrificial mold layer SFL.

In some embodiments, a process of removing the sacrificial mold layer SFL may include (e.g., may be) a wet etching process or a pull-back process. For example, the process of removing the sacrificial mold layer SFL may be an etching process using an etching selectivity between the sacrificial mold layer SFL and the semiconductor layer 120L (the preliminary semiconductor pattern 120P). For example, in the wet etching process or the pull-back process, an etching speed of the plurality of preliminary semiconductor patterns 120P may be relatively low, and an etching speed of the sacrificial mold layer SFL may be relatively high.

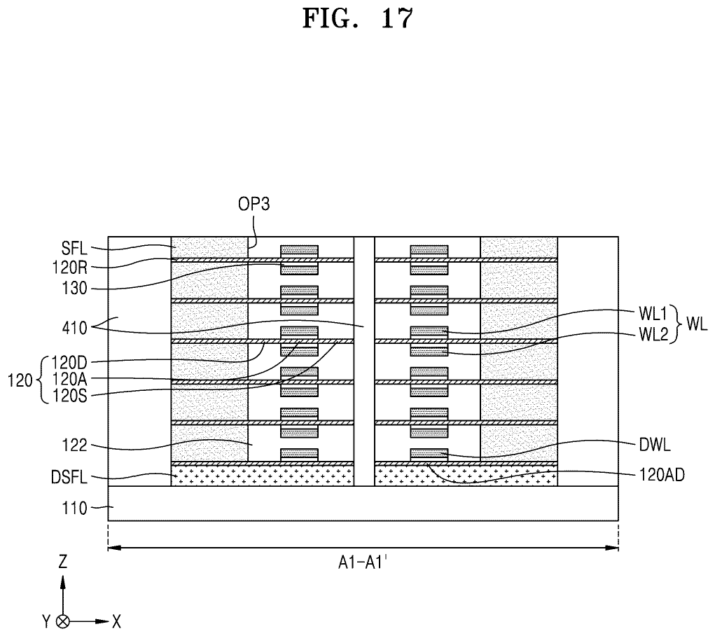

Referring to FIG. 17, the gate insulating layer 130 and the word line WL may be sequentially formed on an upper surface and a lower surface of each of the plurality of semiconductor patterns 120 in the third opening OP3.

In some embodiments, the gate insulating layer 130 may be (conformally) arranged on the lower surface and the upper surface of each of the plurality of semiconductor patterns 120, and the word line WL may extend in the second horizontal direction Y on the gate insulating layer 130. For example, the first word line WL1 may be on the upper surface of the semiconductor pattern 120, and the second word line WL2 may be on the lower surface of the semiconductor pattern 120.

Thereafter, the first impurity region 120S and the second impurity region 120D may be formed. The first impurity region 120S and the second impurity region 120D may be formed at both (opposite) end regions (in the first horizontal direction X) of each of the plurality of semiconductor patterns 120 exposed by partially removing the gate insulating layer 130 and the word line WL (and injecting impurities in the exposed portions of the semiconductor patterns 120 by implantation and/or diffusion). The channel region 120A may be a central region of the semiconductor pattern 120 between the first impurity region 120S and the second impurity region 120D in the first horizontal direction X.

Thereafter, the mold insulating layer 122 may be formed to at least partially fill the inside of the third opening OP3. In some embodiments, the mold insulating layer 122 may be between two word lines WL adjacent in the vertical direction Z and between end regions (the first impurity regions 120S and the second impurity regions 120D) of adjacent two semiconductor patterns 120 in the vertical direction Z.

In this process, the plurality of dummy word lines DWL and a plurality of dummy semiconductor patterns 120AD may be formed. The plurality of dummy semiconductor patterns 120AD may be on the dummy sacrificial mold layer DSFL. The plurality of dummy semiconductor patterns 120AD may be semiconductor patterns that are arranged closest to the first substrate 110 in the vertical direction Z among the plurality of semiconductor patterns 120. The plurality of dummy word lines DWL may be on upper surfaces of the plurality of dummy semiconductor patterns 120AD. The plurality of dummy word lines DWL may be arranged closest to the first substrate 110 in the vertical direction Z among the plurality of word lines WL.

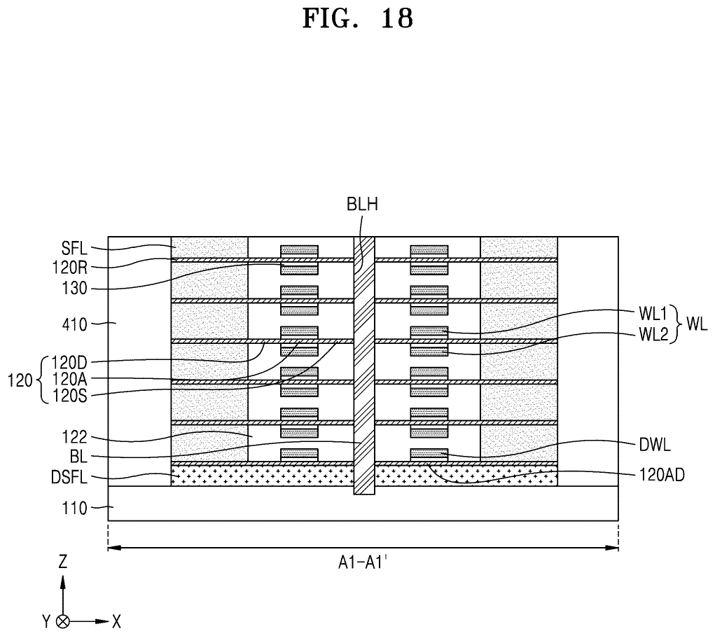

Referring to FIG. 18, part of the separation insulating layer 410 (the separation insulating layer 410 in the second opening OP2) may be removed to form a bit line opening BLH, and the bit line BL may be formed in the bit line opening BLH. In this case, the bit line opening BLH may extend in (e.g., penetrate) part of the first substrate 110. Therefore, the bit line BL may extend in (e.g., pass through) part of the first substrate 110.

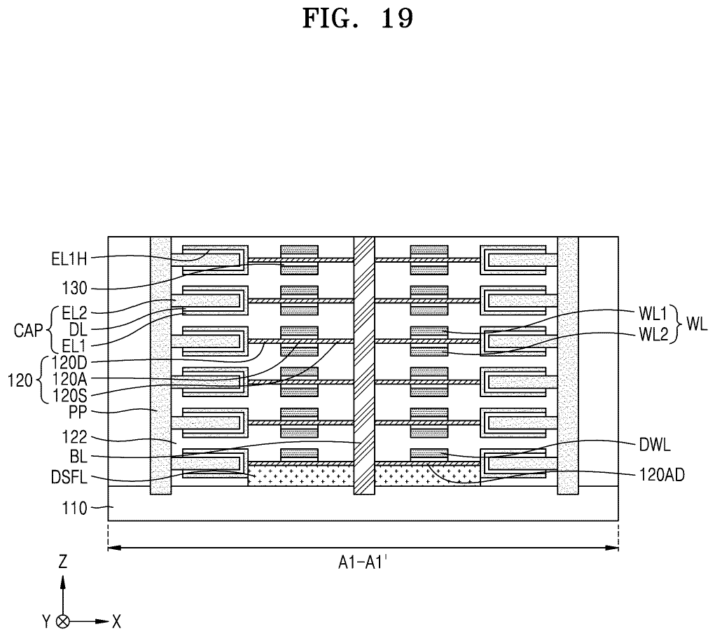

Referring to FIG. 19, the sacrificial mold layer SFL and the residual pattern 120R may be removed, and the cell capacitor CAP may be formed at a position where the sacrificial mold layer SFL and the residual pattern 120R are removed. In this case, part of the dummy sacrificial mold layer DSFL may also be removed.

In some embodiments, the cell capacitor CAP may include the first electrode EL1, the capacitor dielectric layer DL, and the second electrode EL2. The first electrode EL1 may be (electrically) connected to the second impurity region 120D of the semiconductor pattern 120 and may have an internal space EL1H extending in the first horizontal direction X. The capacitor dielectric layer DL may be (conformally) arranged in the internal space EL1H, and the internal space EL1H may be (at least partially) filled with the second electrode EL2.

Thereafter, the plate electrode PP may be formed to be (electrically) connected to the second electrode EL2 and to extend in the second horizontal direction Y. In this case, the plate electrode PP may be extended in (e.g., pass through) part of the first substrate 110.

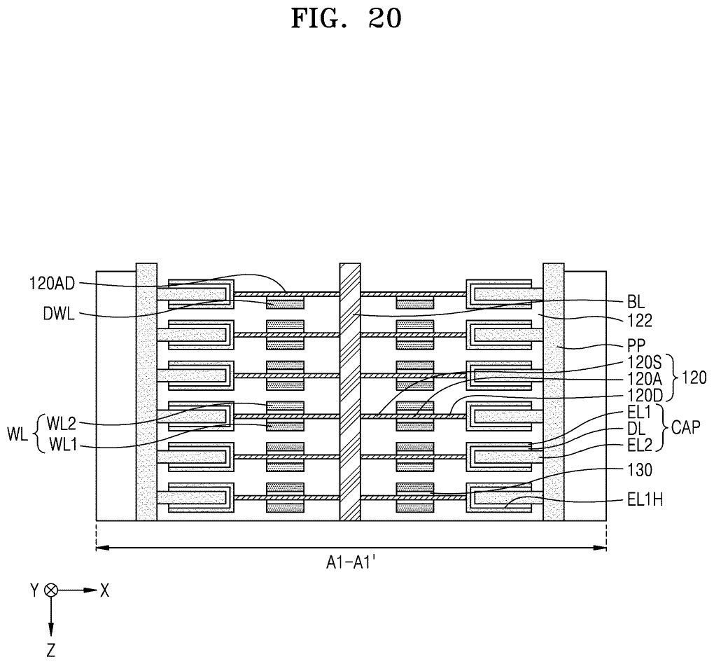

Referring to FIG. 20, after a result of FIG. 19 is turned over, the first substrate 110 (see FIG. 19) may be removed. As the first substrate 110 is removed, part of the bit line BL, part of the plate electrode PP, and one surface of the dummy sacrificial mold layer DSFL may be exposed. Thereafter, the dummy sacrificial mold layer DSFL (e.g., a lower surface of the dummy sacrificial mold layer DSFL in FIG. 19) may be removed, and accordingly, one surface of the dummy semiconductor pattern 120AD and part of the cell capacitor CAP may be exposed.

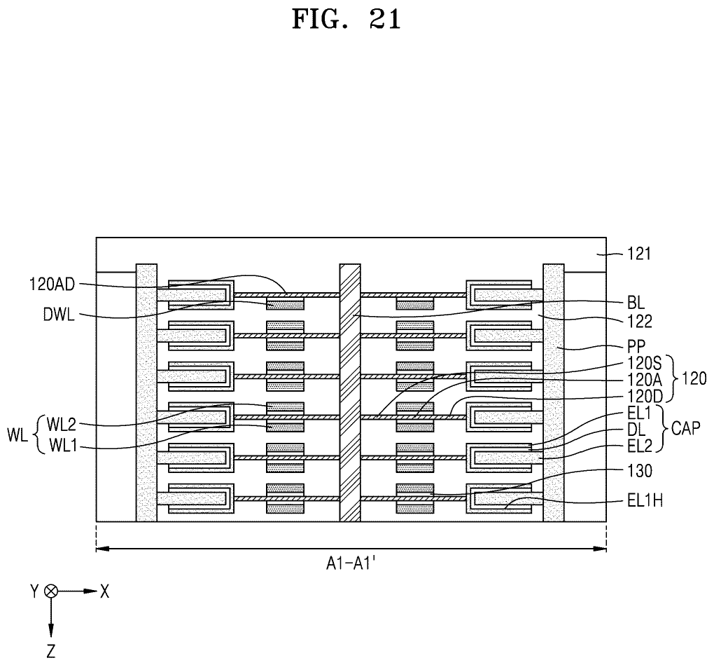

Referring to FIG. 21, the separation insulating layer 121 may be formed in the result of FIG. 20. The separation insulating layer 121 may be on (e.g., may cover) part of the exposed bit line BL and part of the plate electrode PP. Also, the separation insulating layer 121 may be on (e.g., may cover) one surface of the exposed dummy semiconductor pattern 120AD and part of the cell capacitor CAP. The separation insulating layer 121 may be in contact with the dummy semiconductor pattern 120AD. In this case, the separation insulating layer 121 may include a different material from the mold insulating layer 122. When the separation insulating layer 121 includes a different material from the mold insulating layer 122, different insulating materials may be respectively on an upper surface and a lower surface of each of the dummy semiconductor pattern 120AD.

The separation insulating layer 121 may electrically insulate (may separate) the plurality of bit lines BL from each other, the plurality of plate electrodes PP from each other, and between the plurality of bit lines BL and the plurality of plate electrodes PP.

Referring to FIG. 13 again, after a result of FIG. 21 is turned over, an upper wiring structure 150 may be formed. The upper wiring structure 150 may include the wiring layer 152, the via 154, an insulation layer 156, and the contact 158. For example, the contact 158 may be (electrically) connected to the bit line BL, the word line WL, and the plate electrode PP. Thereafter, the first bonding pad BP1 may be formed over (on/in) the upper wiring structure 150 to be on the same plane as an uppermost surface of the insulating layer 156.

Thereafter, the second stack structure SS2 may be provided on the first stack structure SS1. In some embodiments, the second stack structure SS2 may include the second substrate 310, the peripheral circuit transistor 320 on the second substrate 310, the front wiring structure 330 provided on an upper surface of the second substrate 310 to cover the peripheral circuit transistor 320, and the rear wiring structure 340 on a lower surface of the second substrate 310.

In some embodiments, the peripheral circuit transistor 320 may be formed on a first surface (or an upper surface) of the second substrate 310, the front wiring structure 330 may be formed on the first surface of the second substrate 310, a carrier substrate may be attached onto the front wiring structure 330, and then a second surface (or a lower surface) of the second substrate 310 may be ground to thin the second substrate 310. Thereafter, the rear wiring structure 340 and the second bonding pad (BP2) may be formed on the second surface of the second substrate 310, and accordingly, the second stack structure SS2 may be completed (formed).

Thereafter, the second stack structure SS2 may be bonded to the first stack structure SS1, and in this case, the first bonding pad BP1 of the first stack structure SS1 may be bonded to the second bonding pad BP2 of the second stack structure SS2, and an upper surface of the insulation layer 156 may be bonded to a lower surface of the insulation layer 346.

As described above, embodiments of the inventive concept are described with reference to the attached drawings, and those of skill in the art to which the inventive concept belongs will understand that the inventive concept may be modified into other specific forms without changing the technical idea or essential features. Therefore, the embodiments described above are illustrative in all respects and should not be understood as limiting.

While the inventive concept has been particularly shown and described with reference to embodiments thereof, it will be understood that various changes in form and details may be made therein without departing from the scope of the following claims.

1. A semiconductor memory device comprising:
a separation insulating layer;
a plurality of semiconductor patterns that extend in a first horizontal direction on the separation insulating layer, wherein the semiconductor patterns are separated from each other in a second horizontal direction and a vertical direction that intersect the first horizontal direction, wherein each of the semiconductor patterns includes a channel region, a first impurity region, and a second impurity region, and wherein the first impurity region and the second impurity region are arranged in the first horizontal direction with the channel region therebetween;
a plurality of word lines that extend in the second horizontal direction respectively on the plurality of semiconductor patterns;
a plurality of bit lines that extend in the vertical direction on the separation insulating layer, wherein the plurality of bit lines are electrically connected to the first impurity regions of the plurality of semiconductor patterns, respectively;
a plurality of cell capacitors that are electrically connected to the second impurity regions of the plurality of semiconductor patterns, respectively; and
a plate electrode that extends in the vertical direction on the separation insulating layer and is electrically connected to the plurality of cell capacitors,
wherein the first horizontal direction and the second horizontal direction are parallel with an upper surface of the separation insulating layer, and
wherein the vertical direction is perpendicular to the upper surface of the separation insulating layer.

2. The semiconductor memory device of claim 1, wherein a lowermost word line closest to the separation insulating layer in the vertical direction among the plurality of word lines comprises a dummy word line.

3. The semiconductor memory device of claim 2, wherein the dummy word line is configured to receive a negative voltage.

4. The semiconductor memory device of claim 1, wherein a lowermost semiconductor pattern closest to the separation insulating layer in the vertical direction among the plurality of semiconductor patterns comprises dummy semiconductor pattern.

5. The semiconductor memory device of claim 4, wherein a lower surface of the dummy semiconductor pattern is in contact with the upper surface of the separation insulating layer.

6. The semiconductor memory device of claim 4, wherein the plurality of word lines includes a dummy word line on an upper surface of the dummy semiconductor pattern, and
wherein the dummy word line extends in the second horizontal direction.

7. The semiconductor memory device of claim 1, wherein the plurality of bit lines extend into at least a portion of the separation insulating layer in the vertical direction.

8. The semiconductor memory device of claim 1, wherein the plate electrode extends into at least a portion of the separation insulating layer in the vertical direction.

9. The semiconductor memory device of claim 1, wherein each of the plurality of word lines comprises:
a first word line on an upper surface of one of the plurality of semiconductor patterns, wherein the first word line extends in the second horizontal direction; and
a second word line on a lower surface of the one of the plurality of semiconductor patterns, wherein the second word line extends in the second horizontal direction.

10. The semiconductor memory device of claim 1, wherein the plurality of word lines each extend around the plurality of semiconductor patterns, respectively and extend in the second horizontal direction.

11. The semiconductor memory device of claim 1, wherein each of the plurality of cell capacitors includes a first electrode, a capacitor dielectric layer, and a second electrode,
wherein the first electrodes are electrically connected to the second impurity regions of the plurality of semiconductor patterns, respectively, and
wherein the first electrodes each include a space recessed in the first horizontal direction.

12.-15. (canceled)

16. A semiconductor memory device comprising:
a first stack structure that includes a memory cell region that includes a plurality of memory cells and a plurality of cell capacitors; and
a second stack structure that overlaps the plurality of memory cells in a vertical direction, wherein the second stack structure includes a peripheral circuit region that is electrically connected to the plurality of memory cells and on the first stack structure,
wherein the first stack structure comprises:
a separation insulating layer;
a plurality of semiconductor patterns that extend in a first horizontal direction on the separation insulating layer, wherein the semiconductor patterns are separated from each other in a second horizontal direction and the vertical direction that intersect the first horizontal direction, wherein each of the semiconductor patterns includes a channel region, a first impurity region, and a second impurity region, and wherein the first impurity region and the second impurity region are arranged in the first horizontal direction with the channel region therebetween;
a plurality of word lines that extend in the second horizontal direction respectively on the plurality of semiconductor patterns;
a plurality of bit lines that extend in the vertical direction on the separation insulating layer and extend in a first portion of the separation insulating layer, wherein the plurality of bit lines are electrically connected to the first impurity regions of the plurality of semiconductor patterns, respectively; and
a plate electrode that extends in the vertical direction on the separation insulating layer an extends in a second portion of the separation insulating layer, wherein the plate electrode is electrically connected to the plurality of cell capacitors,
wherein the plurality of cell capacitors are electrically connected to the second impurity regions of the plurality of semiconductor patterns, respectively,
wherein the first horizontal direction and the second horizontal direction are parallel with an upper surface of the separation insulating layer, and
wherein the vertical direction is perpendicular to the upper surface of the separation insulating layer.

17. The semiconductor memory device of claim 16, wherein a lowermost word line closest to the separation insulating layer in the vertical direction among the plurality of word lines comprises a dummy word line.

18. The semiconductor memory device of claim 17, wherein the dummy word line is configured to receive a negative voltage.

19. The semiconductor memory device of claim 17, wherein a lowermost semiconductor pattern closest to the separation insulating layer in the vertical direction among the plurality of semiconductor patterns comprises a dummy semiconductor pattern.

20. The semiconductor memory device of claim 19, wherein a lower surface of the dummy semiconductor pattern is in contact with the upper surface of the separation insulating layer.

21. A semiconductor memory device comprising:
a separation insulating layer;
a plurality of semiconductor patterns that extend in a first horizontal direction on the separation insulating layer, wherein the semiconductor patterns are separated from each other in a second horizontal direction and a vertical direction that intersect the first horizontal direction, wherein each of the semiconductor patterns includes a channel region, a first impurity region, and a second impurity region, and wherein the first impurity region and the second impurity region are arranged in the first horizontal direction with the channel region therebetween;
a plurality of word lines that extend in the second horizontal direction respectively on the plurality of semiconductor patterns;
a plurality of bit lines that extend in the vertical direction on the separation insulating layer, wherein the plurality of bit lines are electrically connected to the first impurity regions of the plurality of semiconductor patterns, respectively;
a plurality of cell capacitors that are electrically connected to the second impurity regions of the plurality of semiconductor patterns, respectively; and
a plate electrode that extends in the vertical direction on the separation insulating layer and is electrically connected to the plurality of cell capacitors,
wherein the bit lines are electrically insulated from each other by the separation insulating layer,
wherein the first horizontal direction and the second horizontal direction are parallel with an upper surface of the separation insulating layer, and
wherein the vertical direction is perpendicular to the upper surface of the separation insulating layer.

22. The semiconductor memory device of claim 21, wherein the cell capacitors are electrically insulated from the bit lines by the separation insulating layer.

23. The semiconductor memory device of claim 22, wherein the plate electrode is electrically insulated from the bit lines by the separation insulating layer.

24. The semiconductor memory device of claim 23, wherein the cell capacitors are electrically insulated from each other by the separation insulating layer.
